(19) United States
(12) Patent Application Publication
(10) Pub. No.: US 2025/0116612 A1
(43) Pub. Date: Apr. 10, 2025

(54) METHOD AND APPARATUS FOR MONITORING DEFECT OF SEMICONDUCTOR STRUCTURE

(71) Applicant: UNIVERSITY-INDUSTRY FOUNDATION(UIF), YONSEI UNIVERSITY, Seoul (KR)

(72) Inventors: Mann Ho CHO, Seoul (KR); Jong Hoon KIM, Gimpo-si, Gyeonggi-do (KR); Kwang Sik JEONG, Seoul (KR)

(73) Assignee: UNIVERSITY-INDUSTRY FOUNDATION(UIF), YONSEI UNIVERSITY, Seoul (KR)

(21) Appl. No.: 18/833,914

(22) PCT Filed: Jan. 19, 2023
(86) PCT No.: PCT/KR2023/000937

§ 371 Date: Jul. 28, 2024

(30) Foreign Application Priority Data
Jan. 28, 2022 (KR) 10-2022-0013501

(51) Int. Cl. G01N 21/95; G01N 21/59

(52) U.S. Cl. CPC G01N 21/9501; G01N 21/59; G01N 2201/06113

(57) ABSTRACT

Provided is a semiconductor structure defect monitoring method including injecting a laser beam into a semiconductor structure to form excited carriers in the semiconductor structure; irradiating an electromagnetic wave onto the semiconductor structure while the excited carriers in the semiconductor structure are recombining; measuring characteristic information of the electromagnetic wave reacting with the excited carriers in the semiconductor structure; and determining a defect density or defect distribution of the semiconductor structure by using a parameter including the measured characteristic information of the electromagnetic wave.

### TECHNICAL FIELD

The present invention relates to a monitoring method and monitoring apparatus, and more particularly, to a semiconductor structure defect monitoring method and semiconductor structure defect monitoring apparatus capable of analyzing a defect density or defect distribution of a semiconductor structure in a non-contact and non-destructive manner.

### BACKGROUND ART

Semiconductor technology is evolving from patterns with a size of hundreds of nanometers to ultra-fine patterns with a size of several to tens of nanometers. As such, analysis of the characteristics of defects of a semiconductor structure is critical in semiconductor devices. Therefore, a semiconductor structure defect monitoring method and semiconductor structure defect monitoring apparatus capable of monitoring a defect density or defect distribution of a semiconductor structure in a non-contact and non-destructive manner in a semiconductor manufacturing process needs to be developed. A related document includes Korean Patent Publication No. 10-2004-0106107.

### DETAILED DESCRIPTION OF THE INVENTION

### Technical Problem

The present invention provides a semiconductor structure defect monitoring method and semiconductor structure defect monitoring apparatus capable of analyzing a defect density or defect distribution of a semiconductor structure in a non-contact and non-destructive manner.

However, the above description is an example, and the scope of the present invention is not limited thereto.

### Technical Solution

According to an aspect of the present invention, there is provided a semiconductor structure defect monitoring method including injecting a laser beam into a semiconductor structure to form excited carriers in the semiconductor structure; irradiating an electromagnetic wave onto the semiconductor structure while the excited carriers in the semiconductor structure are recombining; measuring characteristic information of the electromagnetic wave reacting with the excited carriers in the semiconductor structure; and determining a defect density or defect distribution of the semiconductor structure by using a parameter including the measured characteristic information of the electromagnetic wave.

The injecting of the laser beam into the semiconductor structure may include adjusting a wavelength of the laser beam to control a penetration depth of the laser beam into the semiconductor structure.

The injecting of the laser beam into the semiconductor structure may include adjusting an incident angle of the laser beam into the semiconductor structure to control a penetration depth of the laser beam into the semiconductor structure.

The characteristic information of the electromagnetic wave may include a transmittance or reflectance of the electromagnetic wave.

The parameter including the measured characteristic information of the electromagnetic wave may include a transmittance decay change of the electromagnetic wave over time.

The parameter including the measured characteristic information of the electromagnetic wave may include a carrier recombination time constant calculated through inverse Laplace transform on a transmittance decay function of the electromagnetic wave over time.

The carrier recombination time constant may be dividable by type of defects in the semiconductor structure and be inversely proportional to a defect density in the semiconductor structure.

The carrier recombination time constant may be dividable into a first carrier recombination time constant based on a first type of defects in the semiconductor structure and a second carrier recombination time constant based on a second type of defects in the semiconductor structure.

The transmittance decay function of the electromagnetic wave over time may be simulatable by Equation 1.

$$\frac{Δ T}{{T}_{0}} ( t ) = {\sum }_{i = 1}^{n} {a}_{i} {e}^{- t / {τ}_{i}} \qquad ( Equation 1 )$$

(ΔT: a transmittance decay change of the electromagnetic wave, T₀: a transmittance of the electromagnetic wave when the laser beam for forming excited carriers is not injected into the semiconductor structure, n: a number of defect types in the semiconductor structure, aᵢ: a carrier recombination contribution based on each type of defects in the semiconductor structure, t: time, and τᵢ: a carrier recombination time constant based on each type of defects)

The laser beam may include a femtosecond laser beam, and the electromagnetic wave may include a terahertz wave.

The excited carriers in the semiconductor structure may include excited free electrons or holes in the semiconductor structure.

According to another aspect of the present invention, there is provided a semiconductor structure defect monitoring apparatus including: a beam emitter for generating a laser beam to be injected into a semiconductor structure to form excited carriers in the semiconductor structure; an electromagnetic wave irradiator for irradiating an electromagnetic wave onto the semiconductor structure while the excited carriers in the semiconductor structure are recombining; an electromagnetic wave receiver for receiving the electromagnetic wave transmitted through or reflected from the semiconductor structure; a measurer for measuring characteristic information of the electromagnetic wave received by the electromagnetic wave receiver; and an operation controller for determining a defect density or defect distribution of the semiconductor structure by using a parameter including the measured characteristic information of the electromagnetic wave.

The beam emitter may include a wavelength control unit for adjusting a wavelength of the laser beam to control a penetration depth of the laser beam into the semiconductor structure.

The beam emitter may include an incident angle control unit for adjusting an incident angle of the laser beam into the semiconductor structure to control a penetration depth of the laser beam into the semiconductor structure.

The beam emitter may include a wavelength control unit for adjusting a wavelength of the laser beam and an incident angle control unit for adjusting an incident angle of the laser beam into the semiconductor structure, to control a penetration depth of the laser beam into the semiconductor structure.

The electromagnetic wave irradiator may be located above a substrate, and the electromagnetic wave receiver may be located below the substrate to receive the electromagnetic wave transmitted through the semiconductor structure

The electromagnetic wave irradiator may be located above a substrate, and the electromagnetic wave receiver may be located above the substrate to receive the electromagnetic wave reflected from the semiconductor structure.

The measurer may measure a transmittance or reflectance of the electromagnetic wave as the characteristic information of the electromagnetic wave.

The operation controller may calculate a carrier recombination time constant through inverse Laplace transform on a transmittance decay function of the electromagnetic wave over time, as a result using the measured characteristic information of the electromagnetic wave, and the carrier recombination time constant may be dividable by type of defects in the semiconductor structure and be inversely proportional to a defect density in the semiconductor structure.

The beam emitter may generate a femtosecond laser beam, and the electromagnetic wave irradiator may irradiate a terahertz wave.

### Advantageous Effects

According to the afore-described embodiments of the present invention, a semiconductor structure defect monitoring method and semiconductor structure defect monitoring apparatus capable of analyzing a defect density or defect distribution of a semiconductor structure in a non-contact and non-destructive manner may be implemented.

However, the scope of the present invention is not limited to the above effect.

### DESCRIPTION OF THE DRAWINGS

FIG. 1 is a flowchart of a semiconductor structure defect monitoring method according to an embodiment of the present invention.

FIG. 2 is a block diagram of a semiconductor structure defect monitoring apparatus for performing a semiconductor structure defect monitoring method according to an embodiment of the present invention.

FIG. 3 is a diagram for describing a procedure of measuring recombination of free electrons over time by using a semiconductor structure defect monitoring method according to an embodiment of the present invention.

FIG. 4 is a graph showing how a transmittance of an electromagnetic wave decays over time in a semiconductor structure defect monitoring method according to an embodiment of the present invention.

FIG. 5 is a diagram showing a penetration depth of a beam based on an incident angle of the beam.

FIG. 6 is a graph showing how excited free electrons recombine over time based on a wavelength of a laser beam injected into a semiconductor thin film.

FIG. 7 is a graph showing time constants based on wavelengths of a pump beam, which are divided through inverse Laplace transform in a semiconductor structure defect monitoring method according to an embodiment of the present invention.

FIGS. 8 and 9 are graphs showing chemical binding energies of germanium (Ge) near the surface of and inside a semiconductor structure, which are measured using x-ray photoelectron spectroscopy (XPS).

FIG. 10 is a diagram showing a region where electrons are excited by a laser beam injected into a three-dimensional semiconductor structure in a semiconductor structure defect monitoring method of the present invention.

FIG. 11 is a graph comparatively showing how free electrons excited by optical pumping recombine over time in a three-dimensional semiconductor and a planar sample.

FIG. 12 is a diagram comparatively showing regions where electrons are excited by optical pumping based on wavelengths of a laser beam injected into a semiconductor structure for optical pumping.

FIGS. 13 and 14 are diagrams showing changes in shape of a transmittance decay curve based on wavelengths of a laser beam injected into an uneven structure for optical pumping.

FIG. 15 is a diagram comparatively showing regions where electrons are excited by optical pumping based on incident angles of a laser beam injected into a semiconductor structure for optical pumping.

FIGS. 16 and 17 are diagrams showing changes in shape of a transmittance decay curve based on wavelengths of a laser beam injected into an uneven structure for optical pumping.

FIGS. 18 to 23 are diagrams showing portions of semiconductor structure defect monitoring apparatuses according to various embodiments of the present invention.

### MODE OF THE INVENTION

Hereinafter, the present invention will be described in detail by explaining embodiments of the invention with reference to the attached drawings.

The invention may, however, be embodied in many different forms and should not be construed as being limited to the embodiments set forth herein; rather, these embodiments are provided so that this disclosure will be thorough and complete, and will fully convey the concept of the invention to one of ordinary skill in the art. In the drawings, the thicknesses or sizes of layers are exaggerated for clarity and convenience of explanation.

Embodiments of the invention are described herein with reference to schematic illustrations of idealized embodiments (and intermediate structures) of the invention. As such, variations from the shapes of the illustrations as a result, for example, of manufacturing techniques and/or tolerances, are to be expected. Thus, the embodiments of the invention should not be construed as limited to the particular shapes of regions illustrated herein, but are to include deviations in shapes that result, for example, from manufacturing.

As the basic and core element of a semiconductor device, a transistor serves to switch on/off operation of the device by adjusting channel current through a gate. The operating voltage and size of the transistor need to be reduced to develop more efficient and faster devices. However, when only a channel length is shortened, the distance between a source and a drain is reduced and performance reduction is caused by the short-channel phenomenon. To solve such a problem, a fin-field effect transistor (FET) structure in which a silicon channel is placed vertically like the fin of a fish and the gate touches three sides started to be applied. Thereafter, a gate all around (GAA) structure has appeared due to the development of process technology and the demand for lower operating voltages. According to the GAA structure, the gate covers all four sides of the channel to prevent the short-channel phenomenon and the operating voltage is also improved in processes of 4 nanometers or less. Currently, for example, the channel area of the GAA structure is changed into a nanosheet to utilize the entirety of the three-dimensional space of the transistor. This semiconductor device development trend is acting as a huge growth engine in association with ultra-fine pattern process technology. However, defects in an ultra-fine structure may not be easily analyzed due to the limitations of existing electrical defect analysis technology, and thus non-contact and non-destructive optical analysis technology is emerging as a key technology in three-dimensional structural defect analysis.

The present invention relates to a method of analyzing and monitoring defects of a semiconductor structure patterned on a substrate (e.g., a wafer), and an apparatus for performing the method, and more particularly, to a method of analyzing and monitoring a density of defects and a spatial distribution of densities in a planarly and/or three-dimensionally patterned semiconductor structure by analyzing changes in a recombination time constant of carriers optically excited by a femtosecond laser beam injected into the semiconductor structure with various wavelengths and angles by using a transmittance or reflectance of a terahertz beam, and an apparatus for performing the method.

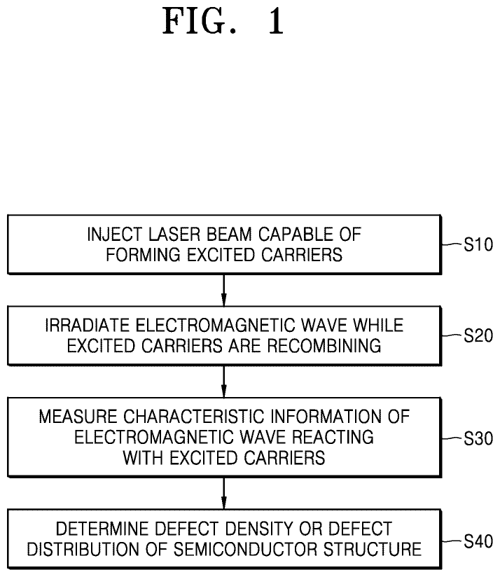

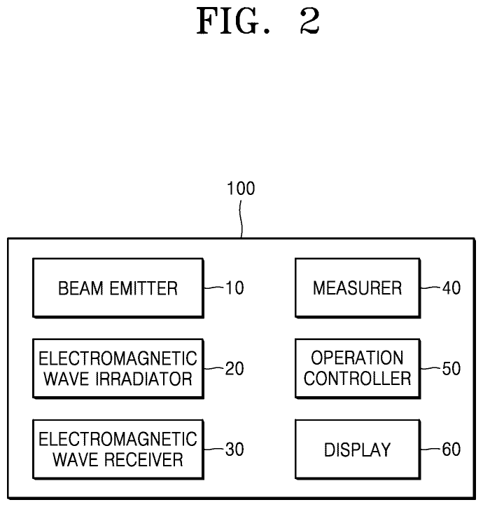

FIG. 1 is a flowchart of a semiconductor structure defect monitoring method according to an embodiment of the present invention, and FIG. 2 is a block diagram of a semiconductor structure defect monitoring apparatus for performing a semiconductor structure defect monitoring method according to an embodiment of the present invention.

Referring to FIG. 1, the semiconductor structure defect monitoring method according to an embodiment of the present invention includes injecting a laser beam into a semiconductor structure to form excited carriers in the semiconductor structure (S10), irradiating an electromagnetic wave onto the semiconductor structure while the excited carriers in the semiconductor structure are recombining (S20), measuring characteristic information of the electromagnetic wave reacting with the excited carriers in the semiconductor structure (S30), and determining a defect density or defect distribution of the semiconductor structure by using a parameter including the measured characteristic information of the electromagnetic wave (S40).

In the semiconductor structure defect monitoring method, the laser beam may include a femtosecond laser beam, and the electromagnetic wave may include a terahertz wave.

In the semiconductor structure defect monitoring method, the characteristic information of the electromagnetic wave may include a transmittance or reflectance of the electromagnetic wave. The parameter including the measured characteristic information of the electromagnetic wave may be a transmittance decay change of the electromagnetic wave over time or a carrier recombination time constant calculated through inverse Laplace transform on a transmittance decay function of the electromagnetic wave over time.

Referring to FIG. 2, a semiconductor structure defect monitoring apparatus 100 for performing the semiconductor structure defect monitoring method according to an embodiment of the present invention includes a beam emitter 10 for generating a laser beam to be injected into a semiconductor structure to form excited carriers in the semiconductor structure, an electromagnetic wave irradiator 20 for irradiating an electromagnetic wave onto the semiconductor structure while the excited carriers in the semiconductor structure are recombining, an electromagnetic wave receiver 30 for receiving the electromagnetic wave transmitted through or reflected from the semiconductor structure, a measurer 40 for measuring characteristic information of the electromagnetic wave received by the electromagnetic wave receiver 30, and an operation controller 50 for determining a defect density or defect distribution of the semiconductor structure by using a parameter including the measured characteristic information of the electromagnetic wave.

The semiconductor structure defect monitoring apparatus 100 may further include a display 60 for displaying the defect density or defect distribution of the semiconductor structure determined by the operation controller 50.

Referring to FIGS. 1 and 2 together, in the semiconductor structure defect monitoring apparatus 100 for performing the semiconductor structure defect monitoring method according to an embodiment of the present invention, the beam emitter 10 may perform at least a portion of the step S10 for injecting the laser beam into the semiconductor structure to form the excited carriers in the semiconductor structure, the irradiator 20 may perform at least a portion of the step S20 for irradiating the electromagnetic wave onto the semiconductor structure while the excited carriers in the semiconductor structure are recombining, the electromagnetic wave receiver 30 and the measurer 40 may perform at least a portion of the step S30 for measuring the characteristic information of the electromagnetic wave reacting with the excited carriers in the semiconductor structure, and the operation controller 50 may perform at least a portion of the step S40 for determining the defect density or defect distribution of the semiconductor structure by using the parameter including the measured characteristic information of the electromagnetic wave.

Although the electromagnetic wave receiver 30 and the measurer 40 are described as separate elements in the semiconductor structure defect monitoring apparatus according to an embodiment of the present invention, in a modified embodiment, the electromagnetic wave receiver 30 and the measurer 40 may be provided as a single element with integrated functions thereof.

The steps of the semiconductor structure defect monitoring method according to an embodiment of the present invention will now be described in detail. Therefore, the following description and the description provided above in relation to FIGS. 1 and 2 may also be applied to the semiconductor structure defect monitoring apparatus 100 for performing the semiconductor structure defect monitoring method of the present invention.

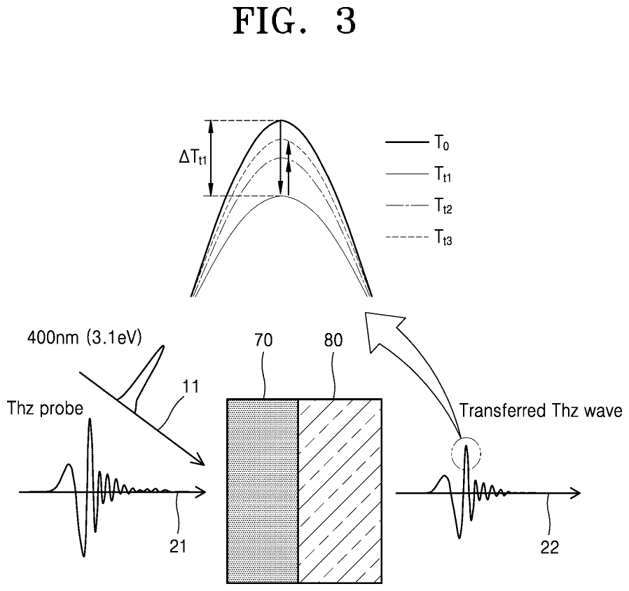

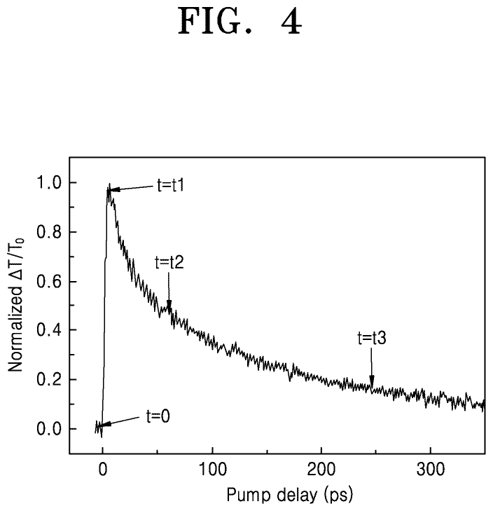

FIG. 3 is a diagram for describing a procedure of measuring recombination of free electrons over time by using a semiconductor structure defect monitoring method according to an embodiment of the present invention, and FIG. 4 is a graph showing how a transmittance of an electromagnetic wave decays over time in a semiconductor structure defect monitoring method according to an embodiment of the present invention.

In FIGS. 3 and 4, ΔT refers to a transmittance decay change of an electromagnetic wave (e.g., a terahertz wave), and T₀ refers to a transmittance of the electromagnetic wave when a laser beam for forming excited carriers is not injected into a semiconductor structure. “Pump delay” refers to a time elapsed from when the laser beam is injected into the semiconductor structure, and t=t1, t=t2, and t=t3 refer to timings at which the terahertz wave is irradiated after the laser beam is injected into the semiconductor structure.

Carriers (e.g., free electrons or holes) excited by a laser beam 11 injected into a semiconductor structure 70 formed on a substrate 80 recombine with a specific time constant through various paths. The laser beam injected into the semiconductor structure 70 may be understood as a pump beam in that it forms excited carriers in the semiconductor structure 70.

The carriers (e.g., free electrons) excited by the injected beam recombine with a specific time constant through various paths. In general, a recombination time constant based on a recombination path includes i) a recombination time constant based on an intra-valley scattering path (<ps), ii) a recombination time constant based on an inter-valley scattering path (to several ps), iii) a recombination time constant based on a defect-assisted recombination path (several ps to several ns), and iv) a recombination time constant based on an inter-band scattering path (hundreds of ps to μs).

Because the time constant of the defect-assisted recombination procedure is inversely proportional to a defect density of a material of the semiconductor structure 70, the defect density of the semiconductor structure 70 may be measured by analyzing the time constant of the recombination procedure.

In this case, to measure recombination of free electrons, for example, a terahertz wave may be used as an electromagnetic wave 21 or 22. For convenience of understanding, FIG. 3 separately shows a terahertz wave after being irradiated from a Thz probe of a beam emitter and before being transmitted through the semiconductor structure 70 (i.e., the electromagnetic wave 21), and a transferred Thz wave after being transmitted through the semiconductor structure 70 (i.e., the electromagnetic wave 22). The terahertz wave is an electromagnetic wave with a frequency of about 0.01 THz to 10 THz and is characterized in that it selectively reacts with excited carriers. Therefore, by measuring changes in intensity of the terahertz wave transmitted through the material of the semiconductor structure 70, the characteristics and quantity of free electrons inside the semiconductor structure 70 may be measured in a non-contact manner.

After a certain time is elapsed from when, for example, a femtosecond laser beam is injected as the laser beam 11 capable of forming excited carriers in the semiconductor structure, when a terahertz wave is transmitted as the electromagnetic wave 21 reacting with the excited carriers, a transmittance of the terahertz wave, i.e., the electromagnetic wave 22, is reduced by free electrons excited in the semiconductor structure 70 by the femtosecond laser beam. Therefore, the quantity of free electrons generated and recombined may be found out in a non-contact and non-destructive manner.

In this case, a recombination time constant of free electrons may be measured by measuring changes in transmittance of the terahertz wave over time after the femtosecond laser beam is injected, and thus a defect density of the semiconductor structure 70 constituting a semiconductor device may be measured in a non-contact and non-destructive manner.

When the excited free electrons recombine through multiple paths, the recombination time constant may be divided into time constants of free electrons recombining through different paths. Using this, when multiple types of defects contribute to defect-assisted recombination, densities of different types of defects may be independently measured by dividing the recombination time constant. That is, the carrier recombination time constant may be divided by type of defects in the semiconductor structure and be inversely proportional to a defect density in the semiconductor structure.

A semiconductor material has various absorption coefficients based on wavelengths. Due to the difference in absorption coefficient, an absorption rate of incident light varies depending on a wavelength, and a penetration depth changes accordingly. In general, the shorter the wavelength, the higher the absorption coefficient and the smaller the penetration depth of the semiconductor material. Therefore, a region where optically excited free electrons occur may be controlled by controlling the wavelength of the light.

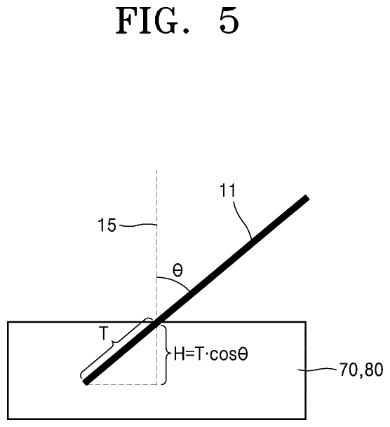

In addition, because a distance by which light passes in the semiconductor material changes depending on an incident angle of the beam, a penetration depth in a vertical direction may be controlled. Referring to FIG. 5 showing a penetration depth of a beam based on an incident angle of the beam, a vertical-direction penetration distance H of the laser beam 11 which is injected at an incident angle θ has a value obtained by multiplying an original penetration distance T by cos θ, i.e., T·cos θ. The incident angle θ may be defined as an angle between a normal line 15 perpendicular to an upper surface of the substrate and semiconductor structure 70 and 80, and a direction of the laser beam 11. A region where optically excited free electrons occur may be controlled by controlling the incident angle of the laser beam for forming excited carriers in the semiconductor structure.

For example, by controlling a wavelength of a femtosecond laser beam for a semiconductor material to control a penetration depth of the laser beam, a region where free electrons are excited may be adjusted to measure a defect density based on a depth from the surface of the semiconductor material.

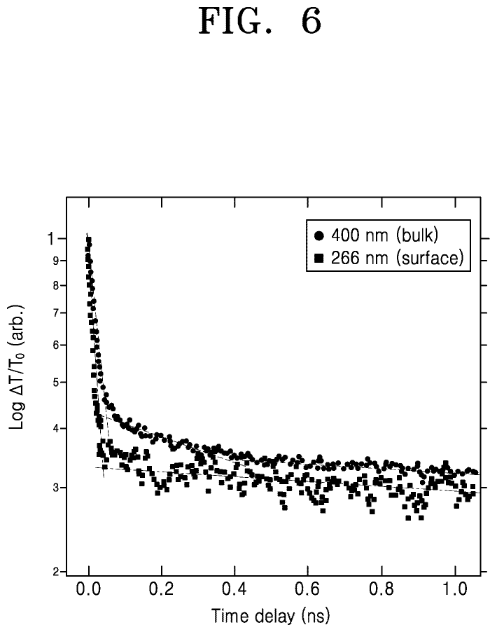

FIG. 6 is a graph showing how excited free electrons recombine over time based on a wavelength of a laser beam injected into a semiconductor thin film. That is, FIG. 6 shows a result of measuring recombination of free electrons over time based on a wavelength after optical pumping is applied to a SiGe thin film.

Referring to FIG. 6, it is shown that recombination of free electrons excited by optical pumping using a 266-nm laser beam differs from recombination of free electrons excited by optical pumping using a 400-nm laser beam. Because a region where free electrons are excited by the 266-nm optical pumping is closer to the surface than a region where free electrons are excited by the 400-nm optical pumping, information indicating that the recombination of the free electrons excited by the 266-nm laser beam over time occurs due to defects near the surface and that the recombination of the free electrons excited by the 400-nm laser beam over time occurs due to defects located deeper from the surface may also be obtained. In an early period of time, the free electrons excited by the 266-nm laser beam recombine fast compared to the free electrons excited by the 400-nm laser beam. In a period of time from 50 ps to 400 ps, only recombination of the free electrons excited by the 400-nm laser beam occurs and recombination of the free electrons excited by the 266-nm laser beam weakly occurs. This is because defects having a fast time constant (e.g., defects a) are distributed at a high density near the surface and defects having a slow time constant (e.g., defects b) are distributed at a low density.

According to the semiconductor structure defect monitoring method of the present invention, a relative ratio of defect densities in a semiconductor structure may be obtained by precisely analyzing time constants through mathematical processing. Electrons excited by the laser beam recombine between hundreds of ps to change the transmittance of the terahertz wave over time and a decay of the transmittance over time in this case satisfies Equation 1 on the assumption that n types of defects are present.

$$\frac{Δ T}{{T}_{0}} ( t ) = {\sum }_{i = 1}^{n} {a}_{i} {e}^{- t / {τ}_{i}} \qquad [ Equation 1 ]$$

(ΔT: a transmittance decay change of an electromagnetic wave, T₀: a transmittance of the electromagnetic wave when a laser beam for forming excited carriers is not injected into a semiconductor structure, n: the number of defect types in the semiconductor structure, aᵢ: a carrier recombination contribution based on each type of defects in the semiconductor structure, t: time, and τᵢ: a carrier recombination time constant based on each type of defects)

When the composition of a semiconductor material is similar, the recombination time constant is inversely proportional to a defect density as shown in Equation 2.

$${τ}_{defect} ∝ \frac{1}{{N}_{defect}} \qquad [ Equation 2 ]$$

(N_{defect}: a defect density, and τ_{defect}: a recombination time constant by defects)

Therefore, a relative ratio of defect densities may be obtained through time constant analysis, and the defect distribution in the semiconductor structure may be obtained for each type of defects.

Meanwhile, due to a subtle difference in defect density in the semiconductor structure, distinguishment may not be easily achieved only based on the decay tendencies. Mathematical processing may be adopted to distinguish time constants between similar decay signals.

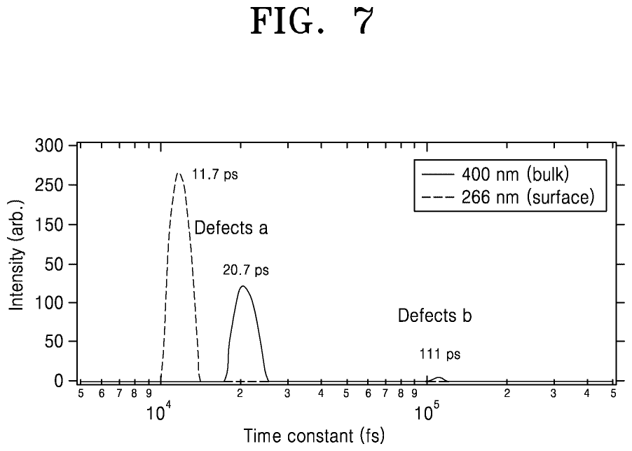

FIG. 7 is a graph showing time constants based on wavelengths of a pump beam, which are divided through inverse Laplace transform in a semiconductor structure defect monitoring method according to an embodiment of the present invention.

In the present invention, it is found that a time-based decay function may be transformed into a time-constant-based function by using inverse Laplace transform and that a decay over time may be transformed into distribution of time constants shown in FIG. 7.

A transmittance change curve of a terahertz wave over time occurs due to a plurality of decay factors. Because measurement data is brought when the influences of all decay factors are added together, a decay curve S(t) is expressed as the integral of a probability density F(k) multiplied by the decay function for all values of k (see Equation 3).

$$S ( t ) = {\int }_{0}^{∞} F ( k ) exp ( - kt ) dk \qquad [ Equation 3 ]$$

This is the same as the Laplace transform formula in form and inverse Laplace transform is required to calculate F(k) indicating the influence of the decay factors. Because F(k) may not be accurately calculated, a procedure of reducing an error rate by applying an approximation function is required and transform is performed by setting a margin of error rate based on a desired accuracy. As a result, an approximation of a time constant k and an approximation of the approximation function F(k) may be obtained, and F(k) may be considered as the influence of the decay factors. FIG. 6 shows a result of transforming a transmittance of a terahertz wave over time into a function related to a time constant by using inverse Laplace transform.

A time constant of defects a is small in the result measured using a 266-nm laser beam but a time constant by defects b is not observed. In addition, when the composition of a semiconductor material is similar, a defect density in the thin film is inversely proportional to a recombination time constant as shown in Equation 2. Therefore, a defect ratio between the surface and bulk of the semiconductor structure measured for defects a may be estimated to be 1.77:1.

For example, a first carrier recombination time constant obtained through time constant analysis may be inversely proportional to a first defect density based on a first type of defects (e.g., defects a), a second carrier recombination time constant may be inversely proportional to a second defect density based on a second type of defects (e.g., defects b), and a size relationship between the first and second carrier recombination time constants may be opposite to the size relationship between the first and second defect densities in the semiconductor structure.

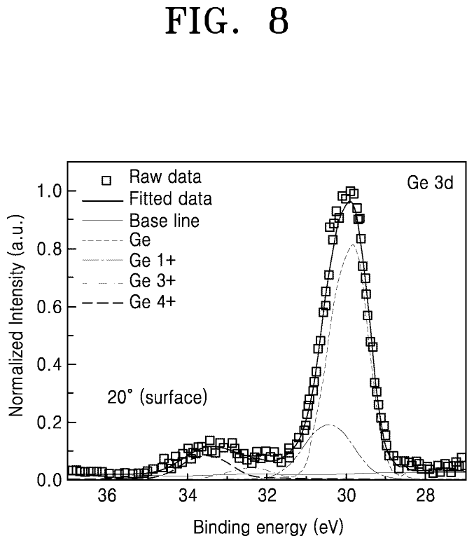

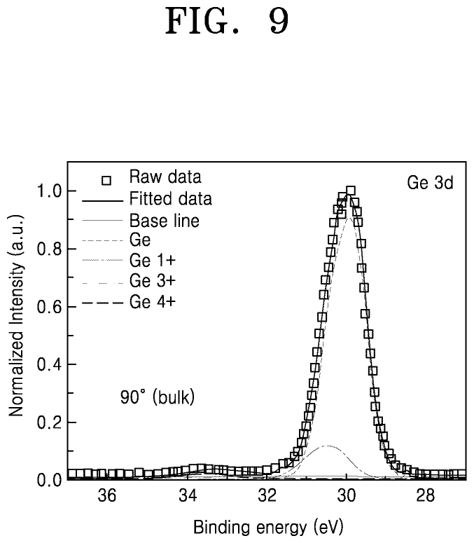

FIGS. 8 and 9 are graphs showing chemical binding energies of germanium (Ge) near the surface of and inside a semiconductor structure, which are measured using x-ray photoelectron spectroscopy (XPS).

Referring to FIGS. 8 and 9, to estimate an approximate distribution of defect densities in a depth direction of the semiconductor structure, XPS was performed per angle on the surface (e.g., 20°) and a deep location (e.g., 90°). The XPS result shows that, in addition to a Ge0 peak caused by Si—Ge binding, a Ge 1+ peak caused by defects exists and that the defects are distributed at a high rate near the surface. Meanwhile, a Ge 3+ peak and a Ge 4+ peak are caused by the oxidation of Ge in the air and are not related to defects.

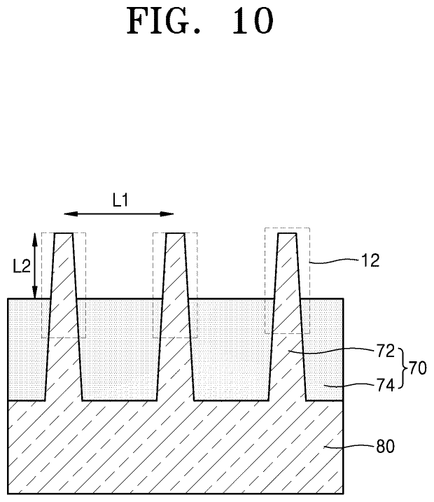

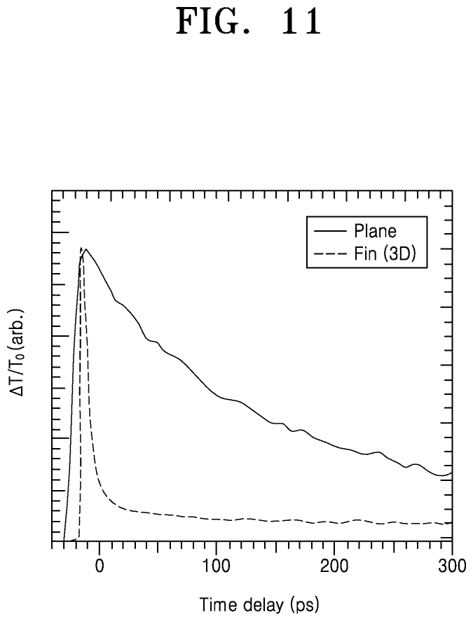

FIG. 10 is a diagram showing a region where electrons are excited by a laser beam injected into a three-dimensional semiconductor structure in a semiconductor structure defect monitoring method of the present invention. L1 is a pitch of patterns, and L2 corresponds to a height of a gate protruding upward from an oxide layer. For example, L1 may be 60 nm, and L2 may be 34 nm. FIG. 11 is a graph comparatively showing how free electrons excited by optical pumping recombine over time in a three-dimensional semiconductor and a planar sample.

Referring to FIG. 10, when a laser beam for optical pumping is injected into a semiconductor thin film patterned in a three-dimensional uneven shape, e.g., a fin-FET, defect analysis is enabled in an uneven portion constituting a channel. Because optical pumping selectively excites only electrons of a semiconductor region, a signal of a gate oxide 74 of the uneven pattern is not measured. Therefore, defect information may be selectively obtained only in a semiconductor region constituting a gate 72. That is, a region 12 where electrons are excited by optical pumping using a laser beam may be formed in a semiconductor region rather than an oxide region.

An etching process is performed to implement a three-dimensional uneven structure and thus defects are formed at a high density near a side of a protruding portion of the semiconductor. Therefore, compared to a thin film, the three-dimensional semiconductor structure made of the same material has a high defect density and thus exhibits fast recombination.

As shown in FIG. 10, electrons distributed near a silicon channel at a side of an uneven portion are optically excited by a pump beam injected in a vertical direction and exhibit a difference in recombination time constant by defects distributed in a three-dimensional space compared to a planar semiconductor sample which is not patterned.

A result of applying optical pumping to an uneven structure and a normal thin film by using a laser beam and then measuring recombination of excited carriers by using a terahertz wave is shown in FIG. 11. Decay characteristics by defects are observed in the uneven structure as in the planar sample. Characteristically, compared to a normal Group 3 or group 5 planar sample, the measurement result of the fin structure shows very fast decay characteristics and is regarded as being caused by the surface recombination phenomenon due to a high area ratio per unit volume of the uneven structure and a high defect density due to the etching procedure.

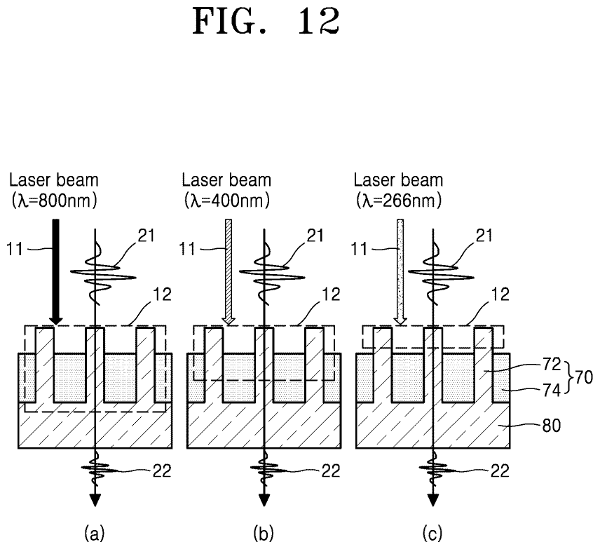

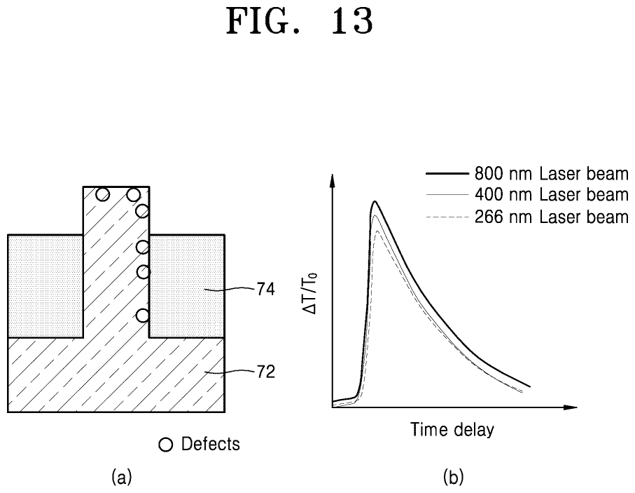

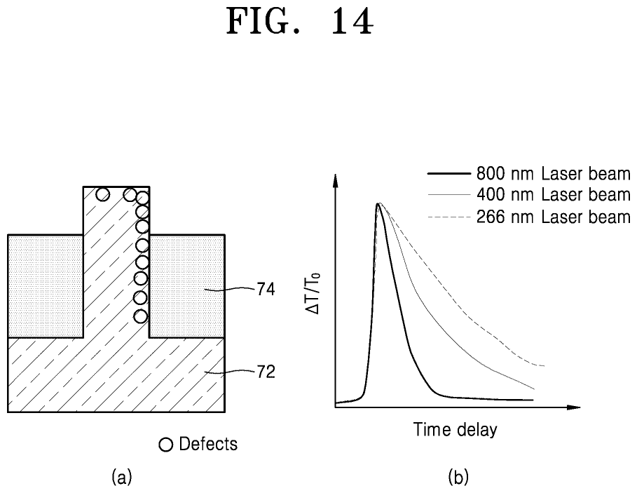

FIG. 12 is a diagram comparatively showing regions where electrons are excited by optical pumping based on wavelengths of a laser beam injected into a semiconductor structure for optical pumping, and FIGS. 13 and 14 are diagrams showing changes in shape of a transmittance decay curve based on wavelengths of a laser beam injected into an uneven structure for optical pumping.

Referring to FIGS. 12 to 14, it may be understood that an incident depth of a pump beam may be controlled by changing a wavelength of the pump beam. When the wavelength of the laser beam for optical pumping is shortened, a penetration depth corresponding to a height of the region 12 where electrons are excited by optical pumping is reduced and a time constant contribution of defects near a side is also reduced. For example, when the top and a side of a protruding portion of a semiconductor uneven structure have similar defect densities as shown in FIG. 13, the decay curve is not changed significantly although the wavelength of the laser beam is changed. On the other hand, when the side of the protruding portion has more defects than the top of the protruding portion due to the etching process as shown in FIG. 14, responsiveness of the side defects to optical pumping is increased in proportion to the wavelength of the laser beam for optical pumping, and a fast decay curve is exhibited compared to a case in which the laser beam is injected with a short wavelength. Therefore, when the change of the decay curve is large depending on the wavelength of the laser beam injected into the semiconductor structure for optical pumping, it may be understood that many defects are present near the side of the semiconductor formed due to the etching process.

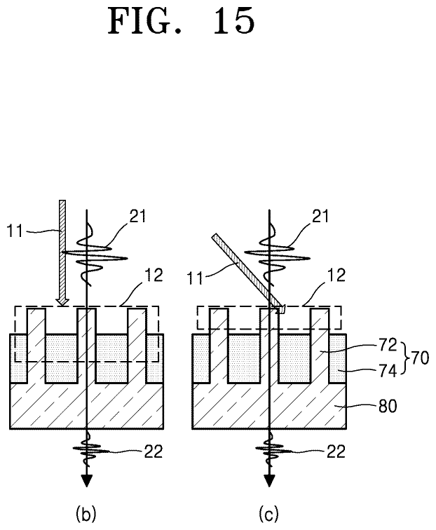

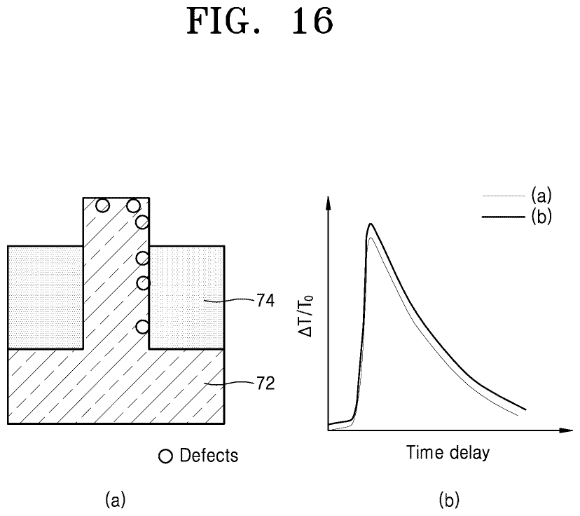

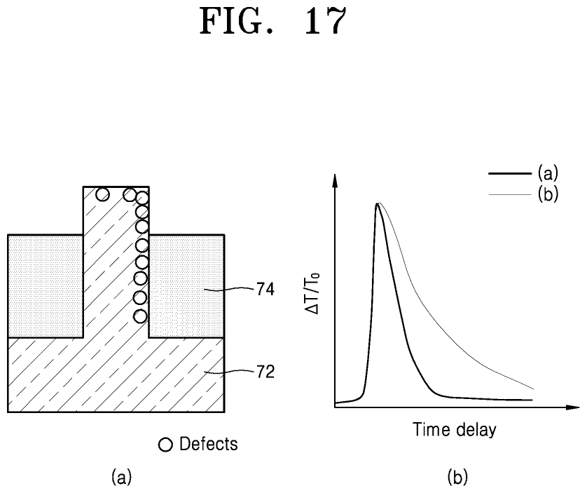

FIG. 15 is a diagram comparatively showing regions where electrons are excited by optical pumping based on incident angles of a laser beam injected into a semiconductor structure for optical pumping, and FIGS. 16 and 17 are diagrams showing changes in shape of a transmittance decay curve based on wavelengths of a laser beam injected into an uneven structure for optical pumping. In FIGS. 16 and 17, (a) corresponds to a case in which an incident angle is relatively small as in (a) of FIG. 15, and (b) corresponds to a case in which an incident angle is relatively large as in (b) of FIG. 15.

As in FIG. 15, an incident depth of a pump beam may be controlled by changing an incident angle of the pump beam. When the incident angle θ (see FIG. 5) is increased while the wavelength of the laser beam 11 for optical pumping is the same, a penetration depth corresponding to a height of the region 12 where electrons are excited by optical pumping is reduced and a time constant contribution of defects near a side is also reduced. For example, when the top and a side of a protruding portion of a semiconductor uneven structure have similar defect densities as shown in FIG. 16, the decay curve is not changed significantly although the incident angle of the laser beam is changed. On the other hand, when the side of the protruding portion has more defects than the top of the protruding portion due to the etching process as shown in FIG. 17, responsiveness of the side defects to optical pumping with a small incident angle is increased and a fast decay curve is exhibited compared to a case in which the laser beam is injected with a large incident angle. Therefore, when the change of the decay curve is large depending on the incident angle of the laser beam injected into the semiconductor structure for optical pumping, it may be understood that many defects are present near the side of the semiconductor formed due to the etching process.

The semiconductor structure defect monitoring methods according to various embodiments of the present invention have been described above. The semiconductor structure defect monitoring method is a method of determining a defect density in a depth direction of a semiconductor based on recombination of free electrons excited by femtosecond laser beams with different penetration depths over time. In addition, the semiconductor structure defect monitoring method is a method of determining a defect density per location in a three-dimensional semiconductor structure based on recombination of free electrons excited by femtosecond laser beams with different penetration depths over time. Furthermore, the semiconductor structure defect monitoring method is a method of dividing defects by type by dividing a recombination time constant of excited free electrons through inverse Laplace transform.

The semiconductor structure defect monitoring method according to an embodiment of the present invention is described above on the assumption that the characteristic information of the electromagnetic wave includes a transmittance of the electromagnetic wave, and that the result using the measured characteristic information of the electromagnetic wave includes a carrier recombination time constant calculated through inverse Laplace transform on a transmittance decay function of the electromagnetic wave over time.

However, in a semiconductor structure defect monitoring method according to a modified embodiment of the present invention, the characteristic information of the electromagnetic wave may include a reflectance of the electromagnetic wave, and the result using the measured characteristic information of the electromagnetic wave may include a carrier recombination time constant calculated through inverse Laplace transform on a reflectance decay function of the electromagnetic wave over time. For example, ΔT of Equation 1 and FIGS. 4, 6, 11, 13, and 14 may be replaced by a reflectance decay change ΔR of the electromagnetic wave, and T₀ of Equation 1 and FIGS. 4, 6, 11, 13, and 14 may be replaced by a reflectance R₀ of the electromagnetic wave when the laser beam for forming excited carriers is not injected into the semiconductor structure. Furthermore, the configuration stating that the carrier recombination time constant is dividable by type of defects in the semiconductor structure and is inversely proportional to a defect density in the semiconductor structure, which is described above with reference to FIG. 7, may be equally applied to a case in which the characteristic information of the electromagnetic wave is the reflectance of the electromagnetic wave as in the case in which the characteristic information of the electromagnetic wave is the transmittance of the electromagnetic wave.

Specific embodiments of semiconductor structure defect monitoring apparatuses for performing the above-described semiconductor structure defect monitoring method of the present invention will now be described. According to the following semiconductor structure defect monitoring apparatuses for performing the semiconductor structure defect monitoring method of the present invention, the characteristics of defects that occur during a process may be easily evaluated without forming additional electrodes or destructing samples during measurement and thus a patterning process may be monitored in real time.

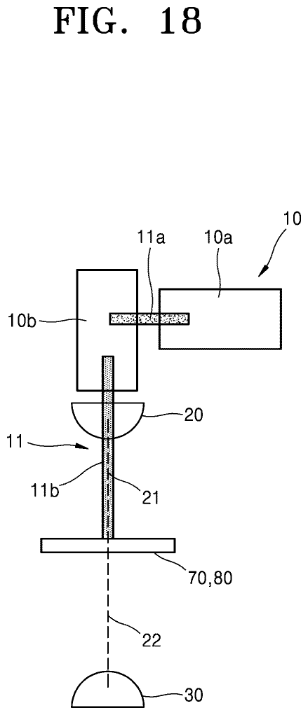

FIGS. 18 to 23 are diagrams showing portions of semiconductor structure defect monitoring apparatuses according to various embodiments of the present invention.

Referring to FIGS. 2 and 18, a semiconductor structure defect monitoring apparatus 100 according to a first embodiment of the present invention includes an electromagnetic wave irradiator 20 for irradiating an electromagnetic wave 21 onto the semiconductor structure 70 while carriers excited in the semiconductor structure 70 by the laser beam 11 are recombining, and an electromagnetic wave receiver 30 for receiving an electromagnetic wave 22 transmitted through the semiconductor structure 70. The electromagnetic wave irradiator 20 is located above the substrate 80, and the electromagnetic wave receiver 30 is located below the substrate 80 to receive the electromagnetic wave 22 transmitted through the semiconductor structure 70.

In the semiconductor structure defect monitoring apparatus 100 according to the first embodiment of the present invention, the beam emitter 10 may include a laser beam generator 10a for generating a laser beam, and a wavelength control unit 10b for adjusting a wavelength of the laser beam 11a generated by the laser beam generator 10a to control a penetration depth of the laser beam into the semiconductor structure 70. That is, the laser beam 11b to be injected into the semiconductor structure 70 may be provided with the wavelength adjusted by the wavelength control unit 10b.

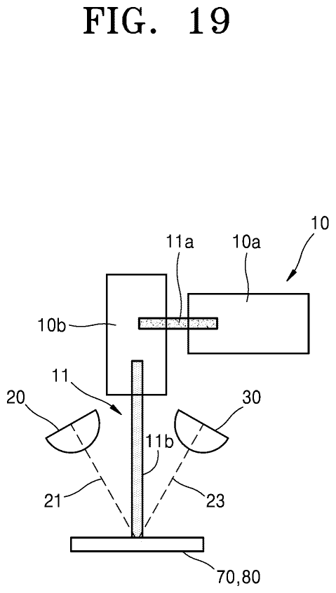

Referring to FIGS. 2 and 19, a semiconductor structure defect monitoring apparatus 100 according to a second embodiment of the present invention includes an electromagnetic wave irradiator 20 for irradiating an electromagnetic wave 21 onto the semiconductor structure 70 while carriers excited in the semiconductor structure 70 by the laser beam 11 are recombining, and an electromagnetic wave receiver 30 for receiving an electromagnetic wave 23 reflected from the semiconductor structure 70. The electromagnetic wave irradiator 20 is located above the substrate 80, and the electromagnetic wave receiver 30 is located above the substrate 80 to receive the electromagnetic wave 23 reflected from the semiconductor structure 70.

In the semiconductor structure defect monitoring apparatus 100 according to the second embodiment of the present invention, the beam emitter 10 may include a laser beam generator 10a for generating a laser beam, and a wavelength control unit 10b for adjusting a wavelength of the laser beam 11a generated by the laser beam generator 10a to control a penetration depth of the laser beam into the semiconductor structure 70. That is, the laser beam 11b to be injected into the semiconductor structure 70 may be provided with the wavelength adjusted by the wavelength control unit 10b.

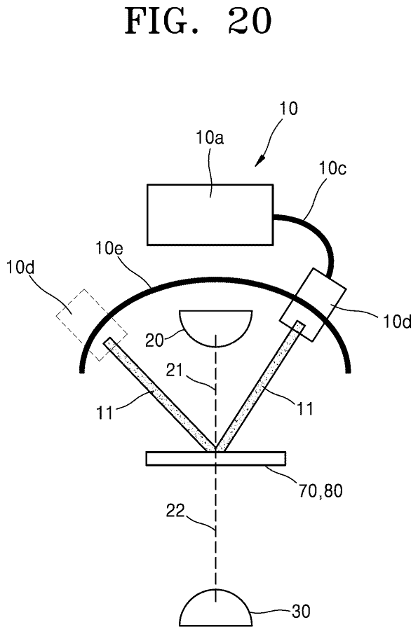

Referring to FIGS. 2 and 20, a semiconductor structure defect monitoring apparatus 100 according to a third embodiment of the present invention includes an electromagnetic wave irradiator 20 for irradiating an electromagnetic wave 21 onto the semiconductor structure 70 while carriers excited in the semiconductor structure 70 by the laser beam 11 are recombining, and an electromagnetic wave receiver 30 for receiving an electromagnetic wave 22 transmitted through the semiconductor structure 70. The electromagnetic wave irradiator 20 is located above the substrate 80, and the electromagnetic wave receiver 30 is located below the substrate 80 to receive the electromagnetic wave 22 transmitted through the semiconductor structure 70.

In the semiconductor structure defect monitoring apparatus 100 according to the third embodiment of the present invention, the beam emitter 10 may include a laser beam generator 10a for generating a laser beam, and an incident angle control unit 10d and 10e for adjusting an incident angle of the laser beam into the semiconductor structure to control a penetration depth of the laser beam into the semiconductor structure 70. The incident angle control unit 10d and 10e may include a first unit 10d for receiving the laser beam generated by the laser beam generator 10a, through an optical fiber 10c and then transmitting the laser beam to the semiconductor structure 70, and a second unit 10e for guiding a path of the first unit 10d to adjust an angle of the first unit 10d. That is, the laser beam 11 to be injected into the semiconductor structure 70 may be provided with the incident angle adjusted by the incident angle control unit 10d and 10e.

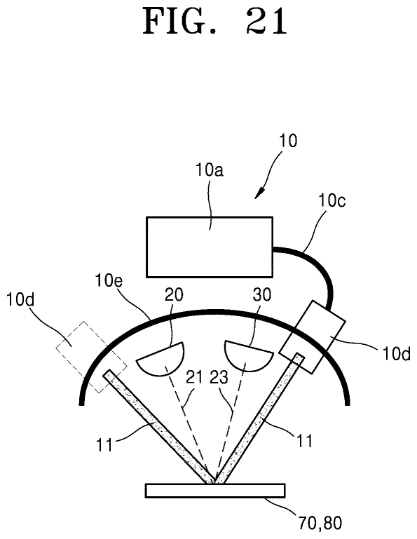

Referring to FIGS. 2 and 21, a semiconductor structure defect monitoring apparatus 100 according to a fourth embodiment of the present invention includes an electromagnetic wave irradiator 20 for irradiating an electromagnetic wave 21 onto the semiconductor structure 70 while carriers excited in the semiconductor structure 70 by the laser beam 11 are recombining, and an electromagnetic wave receiver 30 for receiving an electromagnetic wave 23 reflected from the semiconductor structure 70. The electromagnetic wave irradiator 20 is located above the substrate 80, and the electromagnetic wave receiver 30 is located above the substrate 80 to receive the electromagnetic wave 23 reflected from the semiconductor structure 70.

In the semiconductor structure defect monitoring apparatus 100 according to the fourth embodiment of the present invention, the beam emitter 10 may include a laser beam generator 10a for generating a laser beam, and an incident angle control unit 10d and 10e for adjusting an incident angle of the laser beam into the semiconductor structure to control a penetration depth of the laser beam into the semiconductor structure 70. The incident angle control unit 10d and 10e may include a first unit 10d for receiving the laser beam generated by the laser beam generator 10a, through an optical fiber 10c and then transmitting the laser beam to the semiconductor structure 70, and a second unit 10e for guiding a path of the first unit 10d to adjust an angle of the first unit 10d. That is, the laser beam 11 to be injected into the semiconductor structure 70 may be provided with the incident angle adjusted by the incident angle control unit 10d and 10e.

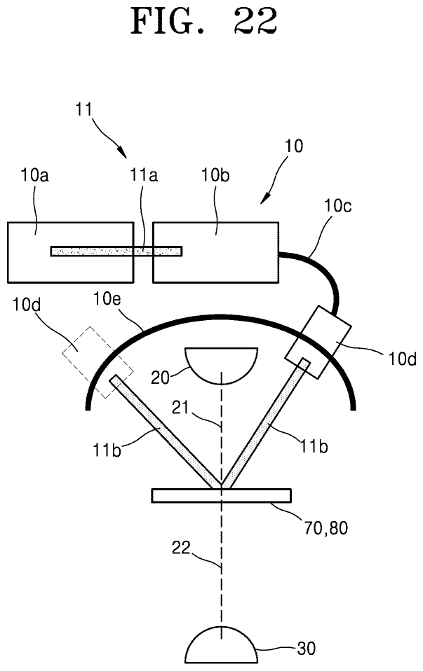

Referring to FIGS. 2 and 22, a semiconductor structure defect monitoring apparatus 100 according to a fifth embodiment of the present invention includes an electromagnetic wave irradiator 20 for irradiating an electromagnetic wave 21 onto the semiconductor structure 70 while carriers excited in the semiconductor structure 70 by the laser beam 11 are recombining, and an electromagnetic wave receiver 30 for receiving an electromagnetic wave 22 transmitted through the semiconductor structure 70. The electromagnetic wave irradiator 20 is located above the substrate 80, and the electromagnetic wave receiver 30 is located below the substrate 80 to receive the electromagnetic wave 22 transmitted through the semiconductor structure 70.

In the semiconductor structure defect monitoring apparatus 100 according to the fifth embodiment of the present invention, the beam emitter 10 may include a laser beam generator 10a for generating a laser beam, and a wavelength control unit 10b for adjusting a wavelength of the laser beam 11a generated by the laser beam generator 10a to control a penetration depth of the laser beam into the semiconductor structure 70. That is, the laser beam 11b to be injected into the semiconductor structure 70 may be provided with the wavelength adjusted by the wavelength control unit 10b.

In the semiconductor structure defect monitoring apparatus 100 according to the fifth embodiment of the present invention, the beam emitter 10 may further include an incident angle control unit 10d and 10e for adjusting an incident angle of the laser beam into the semiconductor structure to control a penetration depth of the laser beam into the semiconductor structure 70. The incident angle control unit 10d and 10e may include a first unit 10d for receiving the laser beam 11b provided with the wavelength adjusted by the wavelength control unit 10b, through an optical fiber 10c and then transmitting the laser beam 11b to the semiconductor structure 70, and a second unit 10e for guiding a path of the first unit 10d to adjust an angle of the first unit 10d. That is, the laser beam 11b to be injected into the semiconductor structure 70 may be provided with the incident angle adjusted by the incident angle control unit 10d and 10e.

Therefore, in the semiconductor structure defect monitoring apparatus 100 according to the fifth embodiment of the present invention, to control the penetration depth of the laser beam into the semiconductor structure 70, the laser beam 11b to be injected into the semiconductor structure 70 may be provided with the wavelength adjusted by the wavelength control unit 10b and the incident angle adjusted by the incident angle control unit 10d and 10e.

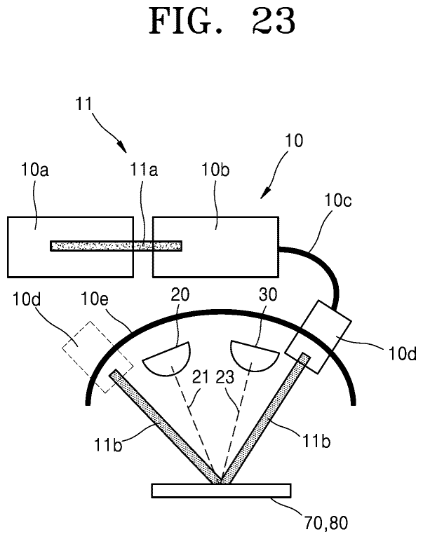

Referring to FIGS. 2 and 23, a semiconductor structure defect monitoring apparatus 100 according to a sixth embodiment of the present invention includes an electromagnetic wave irradiator 20 for irradiating an electromagnetic wave 21 onto the semiconductor structure 70 while carriers excited in the semiconductor structure 70 by the laser beam 11 are recombining, and an electromagnetic wave receiver 30 for receiving an electromagnetic wave 23 reflected from the semiconductor structure 70. The electromagnetic wave irradiator 20 is located above the substrate 80, and the electromagnetic wave receiver 30 is located above the substrate 80 to receive the electromagnetic wave 23 reflected from the semiconductor structure 70.

In the semiconductor structure defect monitoring apparatus 100 according to the sixth embodiment of the present invention, the beam emitter 10 may include a laser beam generator 10a for generating a laser beam, and a wavelength control unit 10b for adjusting a wavelength of the laser beam 11a generated by the laser beam generator 10a to control a penetration depth of the laser beam into the semiconductor structure 70. That is, the laser beam 11b to be injected into the semiconductor structure 70 may be provided with the wavelength adjusted by the wavelength control unit 10b.

In the semiconductor structure defect monitoring apparatus 100 according to the sixth embodiment of the present invention, the beam emitter 10 may further include an incident angle control unit 10d and 10e for adjusting an incident angle of the laser beam into the semiconductor structure to control a penetration depth of the laser beam into the semiconductor structure 70. The incident angle control unit 10d and 10e may include a first unit 10d for receiving the laser beam 11b provided with the wavelength adjusted by the wavelength control unit 10b, through an optical fiber 10c and then transmitting the laser beam 11b to the semiconductor structure 70, and a second unit 10e for guiding a path of the first unit 10d to adjust an angle of the first unit 10d. That is, the laser beam 11b to be injected into the semiconductor structure 70 may be provided with the incident angle adjusted by the incident angle control unit 10d and 10e.

Therefore, in the semiconductor structure defect monitoring apparatus 100 according to the sixth embodiment of the present invention, to control the penetration depth of the laser beam into the semiconductor structure 70, the laser beam 11b to be injected into the semiconductor structure 70 may be provided with the wavelength adjusted by the wavelength control unit 10b and the incident angle adjusted by the incident angle control unit 10d and 10e.

The semiconductor structure defect monitoring apparatuses according to various embodiments of the present invention have been described above. The semiconductor structure defect monitoring apparatus may be understood as an apparatus including a wavelength controller for controlling a penetration depth of a femtosecond laser beam, and/or an angle controller for controlling an incident angle of the femtosecond laser beam, to measure depth-direction defect density information of a semiconductor.

Meanwhile, in an apparatus for controlling a region where a defect density is measured, by controlling an incident depth by controlling a wavelength of a femtosecond laser beam, the controlled wavelength may be, for example, 200 nm to 1500 nm.

Meanwhile, in an apparatus for controlling a region where a defect density is measured, by controlling an incident depth of light by controlling an incident angle of a femtosecond laser beam, the incident angle of the femtosecond laser beam may be, for example, 10° to 90°.

While the present invention has been particularly shown and described with reference to embodiments thereof, it will be understood by one of ordinary skill in the art that various changes in form and details may be made therein without departing from the scope of the present invention as defined by the following claims.

1. A semiconductor structure defect monitoring method comprising:
injecting a laser beam into a semiconductor structure to form excited carriers in the semiconductor structure;
irradiating an electromagnetic wave onto the semiconductor structure while the excited carriers in the semiconductor structure are recombining;
measuring characteristic information of the electromagnetic wave reacting with the excited carriers in the semiconductor structure; and
determining a defect density or defect distribution of the semiconductor structure by using a parameter comprising the measured characteristic information of the electromagnetic wave.

2. The semiconductor structure defect monitoring method of claim 1, wherein the injecting of the laser beam into the semiconductor structure comprises adjusting a wavelength of the laser beam to control a penetration depth of the laser beam into the semiconductor structure.

3. The semiconductor structure defect monitoring method of claim 1, wherein the injecting of the laser beam into the semiconductor structure comprises adjusting an incident angle of the laser beam into the semiconductor structure to control a penetration depth of the laser beam into the semiconductor structure.

4. The semiconductor structure defect monitoring method of claim 1, wherein the characteristic information of the electromagnetic wave comprises a transmittance or reflectance of the electromagnetic wave.

5. The semiconductor structure defect monitoring method of claim 1, wherein the parameter comprising the measured characteristic information of the electromagnetic wave comprises a transmittance decay change of the electromagnetic wave over time.

6. The semiconductor structure defect monitoring method of claim 1, wherein the parameter comprising the measured characteristic information of the electromagnetic wave comprises a carrier recombination time constant calculated through inverse Laplace transform on a transmittance decay function of the electromagnetic wave over time.

7. The semiconductor structure defect monitoring method of claim 6, wherein the carrier recombination time constant is dividable by type of defects in the semiconductor structure and is inversely proportional to a defect density in the semiconductor structure.

8. The semiconductor structure defect monitoring method of claim 7, wherein the carrier recombination time constant is dividable into a first carrier recombination time constant based on a first type of defects in the semiconductor structure and a second carrier recombination time constant based on a second type of defects in the semiconductor structure.

9. The semiconductor structure defect monitoring method of claim 6, wherein the transmittance decay function of the electromagnetic wave over time is simulatable by Equation 1:
$$\frac{Δ T}{{T}_{0}} ( t ) = {\sum }_{i = 1}^{n} {a}_{i} {e}^{- t / {τ}_{i}} \qquad ( Equation 1 )$$
(ΔT: a transmittance decay change of the electromagnetic wave, T₀: a transmittance of the electromagnetic wave when the laser beam for forming excited carriers is not injected into the semiconductor structure, n: a number of defect types in the semiconductor structure, aᵢ: a carrier recombination contribution based on each type of defects in the semiconductor structure, t: time, and τᵢ: a carrier recombination time constant based on each type of defects).

10. The semiconductor structure defect monitoring method of claim 1,
wherein the laser beam comprises a femtosecond laser beam, and the electromagnetic wave comprises a terahertz wave.

11. The semiconductor structure defect monitoring method of claim 1,
wherein the excited carriers in the semiconductor structure comprise excited free electrons or holes in the semiconductor structure.

12. A semiconductor structure defect monitoring apparatus comprising:
a beam emitter for generating a laser beam to be injected into a semiconductor structure to form excited carriers in the semiconductor structure;
an electromagnetic wave irradiator for irradiating an electromagnetic wave onto the semiconductor structure while the excited carriers in the semiconductor structure are recombining;
an electromagnetic wave receiver for receiving the electromagnetic wave transmitted through or reflected from the semiconductor structure;
a measurer for measuring characteristic information of the electromagnetic wave received by the electromagnetic wave receiver; and
an operation controller for determining a defect density or defect distribution of the semiconductor structure by using a parameter comprising the measured characteristic information of the electromagnetic wave.

13. The semiconductor structure defect monitoring apparatus of claim 12, wherein the beam emitter comprises a wavelength control unit for adjusting a wavelength of the laser beam to control a penetration depth of the laser beam into the semiconductor structure.

14. The semiconductor structure defect monitoring apparatus of claim 12, wherein the beam emitter comprises an incident angle control unit for adjusting an incident angle of the laser beam into the semiconductor structure to control a penetration depth of the laser beam into the semiconductor structure.

15. The semiconductor structure defect monitoring apparatus of claim 12, wherein the beam emitter comprises a wavelength control unit for adjusting a wavelength of the laser beam and an incident angle control unit for adjusting an incident angle of the laser beam into the semiconductor structure, to control a penetration depth of the laser beam into the semiconductor structure.

16. The semiconductor structure defect monitoring apparatus of claim 12, wherein the electromagnetic wave irradiator is located above a substrate, and the electromagnetic wave receiver is located below the substrate to receive the electromagnetic wave transmitted through the semiconductor structure.

17. The semiconductor structure defect monitoring apparatus of claim 12, wherein the electromagnetic wave irradiator is located above a substrate, and the electromagnetic wave receiver is located above the substrate to receive the electromagnetic wave reflected from the semiconductor structure.

18. The semiconductor structure defect monitoring apparatus of claim 12, wherein the measurer measures a transmittance or reflectance of the electromagnetic wave as the characteristic information of the electromagnetic wave.

19. The semiconductor structure defect monitoring apparatus of claim 12, wherein the operation controller calculates a carrier recombination time constant through inverse Laplace transform on a transmittance decay function of the electromagnetic wave over time, as a result using the measured characteristic information of the electromagnetic wave, and the carrier recombination time constant is dividable by type of defects in the semiconductor structure and is inversely proportional to a defect density in the semiconductor structure.

20. The semiconductor structure defect monitoring apparatus of claim 12, wherein the beam emitter generates a femtosecond laser beam, and the electromagnetic wave irradiator irradiates a terahertz wave.
